(19) United States
(12) Patent Application Publication
(10) Pub. No.: US 2025/0242392 A1
(43) Pub. Date: Jul. 31, 2025

(54) SUBSTRATE DRYING METHOD AND SUBSTRATE TREATING METHOD

(71) Applicant: SCREEN Holdings Co., Ltd., Kyoto (JP)

(72) Inventors: Yuta SASAKI, Kyoto (JP); Shogo KUNIEDA, Kyoto (JP)

(21) Appl. No.: 18/848,123

(22) PCT Filed: Mar. 17, 2023
(86) PCT No.: PCT/JP2023/010619

§ 371 Date: Sep. 17, 2024

(30) Foreign Application Priority Data
Mar. 22, 2022 (JP) 2022-045264

(51) Int. Cl. B08B 7/00; B08B 3/10; F26B 5/00; H01L 21/02

(52) U.S. Cl. CPC B08B 7/0071; B08B 3/10; F26B 5/005; H01L 21/02057

(57) ABSTRACT

The present invention relates to a substrate drying method and a substrate treating method. The substrate drying method is to dry the substrate W on which the pattern P is formed. The substrate drying method includes an application step, a curing step, and a thermal decomposition step. In the application step, the dry assistant liquid F is applied to the substrate W. The dry assistant liquid F contains an ultraviolet curable material. In the curing step, the dry assistant liquid F on the substrate W is irradiated with ultraviolet rays. In the curing step, the solidified film H is formed on the substrate W. In the thermal decomposition step, the solidified film H is heated and thus the solidified film His thermally decomposed. In the thermal decomposition step, the substrate W is dried.

### TECHNICAL FIELD

The present invention relates to a substrate drying method and a substrate treating method. The substrate is, for example, a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, a solar cell substrate.

### BACKGROUND ART

Patent Literature 1 discloses a substrate treating method for treating a substrate. The substrate treating method of Patent Literature 1 includes a treatment step, a replacement step, and a removal step. In the treatment step, a rinse liquid is supplied to a substrate. In the replacement step, the rinse liquid on the substrate is replaced with an organic solvent. In the removal step, the organic solvent is removed from the substrate. The substrate is dried by the removal step.

### CITATION LIST

### Patent Literature

Patent Literature 1: JP 2012-156561 A

### SUMMARY OF INVENTION

### Technical Problem

Even in the conventional substrate treating method, there is a case where the substrate cannot be appropriately treated. For example, when the substrate has a pattern, the pattern may collapse even in the conventional substrate treating method. For example, when the pattern is fine, the collapse of the pattern may not be sufficiently suppressed even by the conventional substrate treating method.

The present invention has been made in consideration of such circumstances, and an object of the present invention is to provide a substrate drying method capable of appropriately drying a substrate and a substrate treating method capable of appropriately treating a substrate.

### Solution to Problem

In order to achieve such an object, the present invention has the following construction. That is, the present invention is a substrate drying method for drying a substrate on which a pattern is formed, the substrate drying method including: an application step of applying a dry assistant liquid containing an ultraviolet curable material to the substrate: a curing step of irradiating the dry assistant liquid on the substrate with ultraviolet rays to form a solidified film on the substrate; and a thermal decomposition step of heating the solidified film to thermally decompose the solidified film and drying the substrate.

The substrate drying method is to dry a substrate on which a pattern is formed. The substrate drying method includes an application step, a curing step, and a thermal decomposition step. In the application step, a dry assistant liquid is applied to the substrate. The dry assistant liquid contains an ultraviolet curable material. In the curing step, the dry assistant liquid on the substrate is irradiated with ultraviolet rays. In the curing step, a solidified film is formed on the substrate. In the thermal decomposition step, the solidified film on the substrate is heated, and thus the solidified film is decomposed by heat. In the thermal decomposition step, the substrate is dried.

As described above, the substrate drying method includes the application step and the curing step. Accordingly, the solidified film is suitably formed on the substrate. Further, the solidified film suitably supports the pattern of the substrate. The substrate drying method further includes the thermal decomposition step. Accordingly, the solidified film is suitably decomposed by heat. Thus, the solidified film is suitably removed from the substrate. Therefore, the substrate is dried in a state where the pattern is protected.

As described above, according to the substrate drying method, the substrate is appropriately dried.

In the substrate drying method described above, the solidified film preferably has thermal decomposability. In the thermal decomposition step, the solidified film is suitably thermally decomposed. Thus, the substrate is more appropriately dried.

In the substrate drying method described above, in the thermal decomposition step, the solidified film is preferably heated at a temperature equal to or higher than the thermal decomposition temperature of the solidified film. In the thermal decomposition step, the solidified film is more suitably thermally decomposed. Thus, the substrate is more appropriately dried.

In the substrate drying method described above, in the thermal decomposition step, the solidified film is preferably heated at a temperature of 700 degrees or higher. It is easy to set the heating temperature of the solidified film to be equal to or higher than the thermal decomposition temperature of the solidified film.

In the substrate drying method described above, in the thermal decomposition step, the solidified film is preferably removed from the substrate by thermal decomposition of the solidified film. After the thermal decomposition step, the solidified film does not remain on the substrate. Thus, a clean substrate is obtained after the thermal decomposition step. Therefore, the substrate is more appropriately dried.

In the substrate drying method described above, in the thermal decomposition step, the solidified film is preferably gasified. In the thermal decomposition step, the solidified film is suitably removed from the substrate.

In the substrate drying method described above, it is preferable that, in the thermal decomposition step, the solidified film is decomposed into a plurality of particles, and the particles float from the substrate. In the thermal decomposition step, the solidified film is suitably removed from the substrate.

In the substrate drying method described above, in the thermal decomposition step, the solidified film is preferably removed from the substrate without being melted. When the solidified film is thermally decomposed, the force acting on the pattern is even lower. Thus, even when the solidified film is thermally decomposed, the pattern is suitably protected.

In the substrate drying method described above, it is preferable that, in the curing step, the ultraviolet curable material becomes a polymer, the solidified film includes the polymer, and in the thermal decomposition step, the polymer is thermally decomposed. In the curing step, the ultraviolet curable material becomes a polymer. The solidified film contains the polymer of the ultraviolet curable material. Accordingly, in the curing step, the solidified film is suitably formed. In the thermal decomposition step, the polymer of the ultraviolet curable material is thermally decomposed. Thus, in the thermal decomposition step, the solidified film is suitably thermally decomposed.

In the substrate drying method described above, the ultraviolet curable material is preferably a liquid. It is easy to obtain the dry assistant liquid from the ultraviolet curable material.

In the substrate drying method described above, the ultraviolet curable material preferably does not contain a polymer. It is easy to obtain a liquid of the ultraviolet curable material.

In the substrate drying method described above, the ultraviolet curable material is preferably isobornyl acrylate. When the ultraviolet curable material is isobornyl acrylate, the pattern is more suitably protected. Thus, the substrate is more appropriately dried.

In the substrate drying method described above, the ultraviolet curable material is preferably an isobornyl acrylate monomer. The substrate is more appropriately dried. Furthermore, it is easier to obtain a liquid of the ultraviolet curable material.

In the substrate drying method described above, it is preferable that the dry assistant liquid does not contain a solvent. Accordingly, in the curing step and the thermal decomposition step, no solvent is present on the substrate. Therefore, it is easier to protect the pattern in the curing step and the thermal decomposition step.

In the substrate drying method described above, the dry assistant liquid preferably further contains a polymerization initiator. In the curing step, the polymerization initiator promotes polymerization of the ultraviolet curable material. Thus, in the curing step, the solidified film is rapidly formed.

In the substrate drying method described above, it is preferable that a part of the dry assistant liquid remains on the substrate at the end of the curing step and that in the thermal decomposition step, the dry assistant liquid remaining on the substrate at the end of the curing step is further evaporated. Even when a part of the dry assistant liquid remains on the substrate at the end of the curing step, the substrate is appropriately dried in the thermal decomposition step.

In the substrate drying method described above, the boiling point of the dry assistant liquid is preferably lower than the thermal decomposition temperature of the solidified film. In the thermal decomposition step, the dry assistant liquid evaporates, and then the solidified film is thermally decomposed. In other words, in the thermal decomposition step, the solidified film is not substantially thermally decomposed until the dry assistant liquid evaporates. Thus, in the thermal decomposition step, the pattern is protected by the solidified film until the dry assistant liquid evaporates. Therefore, the substrate is appropriately dried.

In the substrate drying method described above, the boiling point of the ultraviolet curable material is preferably lower than the thermal decomposition temperature of the solidified film. In the thermal decomposition step, the dry assistant liquid suitably evaporates before the solidified film is thermally decomposed.

In the substrate drying method described above, it is preferable that the dry assistant liquid entirely disappears from the substrate at the end of the curing step. For example, at the end of the curing step, the entire dry assistant liquid preferably changes to a solidified film. Accordingly, in the thermal decomposition step, the dry assistant liquid is not present on the substrate. Therefore, it is easier to protect the pattern in the thermal decomposition step.

In the substrate drying method described above, the thermal decomposition step preferably includes a first step of heating a substrate at a first temperature and a second step of heating the solidified film at a second temperature higher than the first temperature. In the first step, the substrate is heated. Accordingly, in the first step, the dry assistant liquid is reliably evaporated from the substrate. In the first step, the dry assistant liquid is reliably removed from the substrate. Even when a part of the dry assistant liquid remains on the substrate at the end of the curing step, the entire dry assistant liquid remaining on the substrate is removed from the substrate in the first step. The entire dry assistant liquid remaining on the substrate at the end of the curing step is removed from the substrate without being changed to the solidified film in the first step. Accordingly, in the second step, the dry assistant liquid is not present on the substrate. Therefore, it is easier to protect the pattern in the second step. In the first step, the substrate is heated at the first temperature. In the second step, the solidified film is heated at the second temperature. The first temperature is lower than the second temperature. Thus, in the first step, thermal decomposition of the solidified film is suitably prevented. Therefore, in the first step, the pattern is suitably protected by the solidified film. Meanwhile, the second temperature is higher than the first temperature. Thus, in the second step, the solidified film is suitably thermally decomposed.

In the substrate drying method described above, the first temperature is preferably lower than the thermal decomposition temperature of the solidified film. In the first step, thermal decomposition of the solidified film is more reliably prevented. In the substrate drying method described above, the first temperature is preferably equal to or higher than the boiling point of the dry assistant liquid. In the first step, the dry assistant liquid is more reliably removed from the substrate.

In the substrate drying method described above, the first temperature is preferably equal to or higher than the boiling point of the ultraviolet curable material. In the first step, the dry assistant liquid is more reliably removed from the substrate.

In the substrate drying method described above, the second temperature is preferably equal to or higher than the thermal decomposition temperature of the solidified film. In the second step, the solidified film is more suitably thermally decomposed.

The present invention is a substrate treating method for treating a substrate on which a pattern is formed, the substrate treating method including: a treatment liquid supply step of supplying a treatment liquid to the substrate; and a drying step of executing the substrate drying method described above.

The substrate treating method is to treat a substrate on which a pattern is formed. The substrate treating method includes a treatment liquid supply step and a drying step. In the treatment liquid supply step, a treatment liquid is supplied to a substrate. In the drying step, the above-described substrate drying method is executed. Specifically, the drying step includes an application step, a curing step, and a thermal decomposition step. Thus, the substrate is dried in a state where the pattern is protected.

As described above, according to the substrate treating method, the substrate is appropriately treated.

In the substrate treating method described above, the treatment liquid is preferably removed from the substrate in the application step. Accordingly, in the curing step and the thermal decomposition step, no treatment liquid is present on the substrate. Thus, it is easier to protect the pattern in the curing step and the thermal decomposition step.

### Advantageous Effects of Invention

According to the substrate drying method of the present invention, the substrate is appropriately dried. According to the substrate treating method of the present invention, the substrate is appropriately treated.

### BRIEF DESCRIPTION OF DRAWINGS

FIG. 1 is a view schematically illustrating a part of a substrate.

FIG. 2 is a plan view illustrating an interior of a substrate treating apparatus according to an embodiment.

FIG. 3 is a control block diagram of the substrate treating apparatus.

FIG. 4 is a diagram illustrating a construction of a treating unit.

FIG. 5 is a flowchart showing procedures of a substrate treating method according to the embodiment.

FIG. 6 is a view schematically illustrating the substrate in an application step.

FIG. 7 is a view schematically illustrating the substrate in a curing step.

FIG. 8 is a view schematically illustrating the substrate in the curing step.

FIG. 9 is a view schematically illustrating the substrate in a thermal decomposition step.

FIG. 10 is a view schematically illustrating the substrate in the thermal decomposition step.

FIG. 11 is a view schematically illustrating the substrate in the thermal decomposition step.

FIG. 12 is a view schematically illustrating the substrate in the thermal decomposition step.

FIG. 13 is a graph showing evaluation of a substrate treated according to Example and substrates treated according to Comparative Examples.

FIG. 14 is a flowchart showing procedures of a thermal decomposition step according to a modified embodiment.

FIG. 15 is a diagram illustrating a construction of a treating unit according to a modified embodiment.

FIG. 16 is a left-side diagram illustrating a construction of a left portion of a substrate treating apparatus according to a modified embodiment.

### DESCRIPTION OF EMBODIMENTS

Hereinafter, a substrate drying method and a substrate treating method of the present invention will be described with reference to the drawings.

### 1. Substrate

A substrate W is, for example, a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, a solar cell substrate. The substrate W has a thin and flat plate shape. The substrate W has a substantially circular shape in plan view:

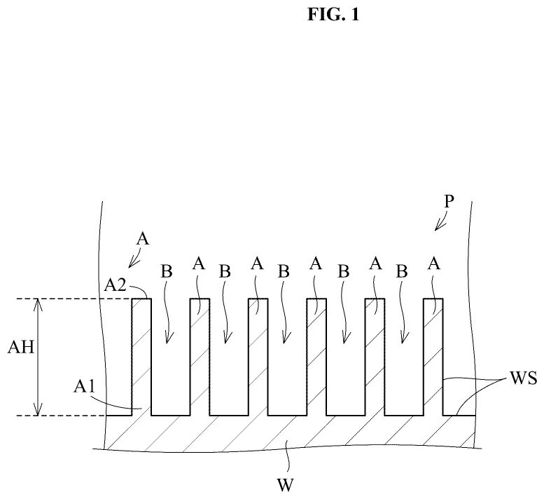

FIG. 1 is a view schematically illustrating a part of the substrate W. The substrate W has a pattern P. The pattern P is formed on a surface WS of the substrate W. The pattern P has, for example, an uneven shape.

The pattern P has, for example, a plurality of projections A. The projections A are part of the substrate W. The projections A are a structure. The projections A are each formed with, for example, at least one of a monocrystalline silicon film, a silicon oxide (SiO₂) film, a silicon nitride (SiN) film, or a polysilicon film. The projections A project from the surface WS. The plurality of projections A are separated from each other.

Each of the projections A has a base end section A1 and a tip section A2. The base end section A1 is connected to a surface WS. Each of the projections A extends from the base end section A1 to the tip section A2.

The projections A have a height AH. A height AH is a length from the base end section A1 to the tip section A2.

The pattern P has a plurality of recesses B. Each of the recesses B is a space. The plurality of recesses B may communicate with each other, for example. Alternatively, the plurality of recesses B may be blocked from each other. A recess B is defined by the projection A. The recess B is located around the projection A. The recess B is located between two or more projections A adjacent to each other.

When the pattern P is directed upward, each of the projections A extends upward. When the pattern P is directed upward, each of the projections A is arranged laterally. When the pattern P is directed upward, the base end section A1 corresponds to a lower end section of each of the projections A. When the pattern P is directed upward, the tip section A2 corresponds to an upper end section of each of the projections A. When the pattern P is directed upward, the recesses B are opened upward.

The base end section A1 may be called “base end section of the pattern P”. The tip section A2 may be called “tip section of the pattern P”. The height AH may be called “height of the pattern P”.

### 2. Outline of Substrate Treating Apparatus 1

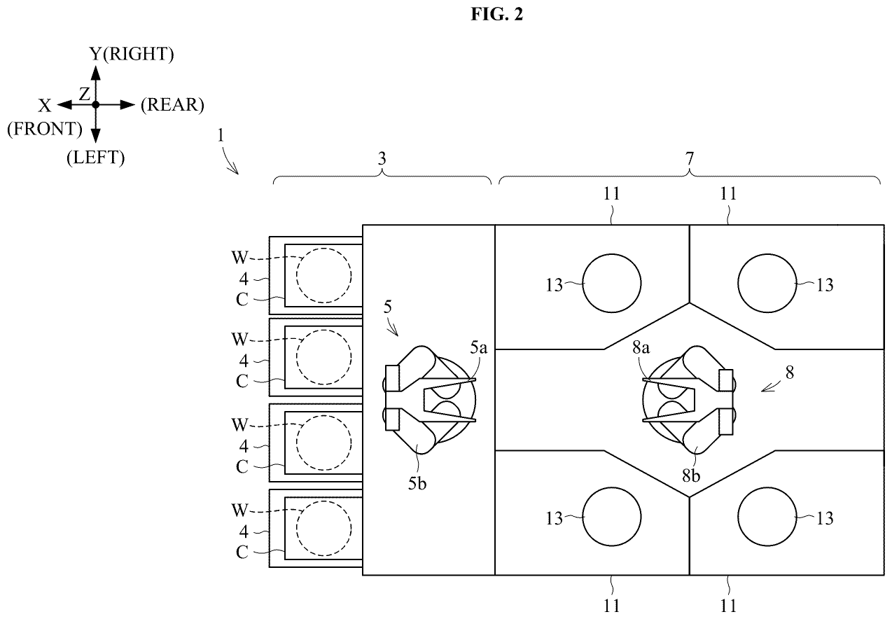

FIG. 2 is a plan view illustrating an interior of a substrate treating apparatus 1 according to an embodiment. A substrate treating apparatus 1 performs treatment on the substrate W. The treatment in the substrate treating apparatus 1 includes a dry treatment.

The substrate treating apparatus 1 includes an indexer 3 and a treating block 7. The treating block 7 is connected to the indexer 3. The indexer 3 supplies the substrate W to the treating block 7. The treating block 7 performs treatment on the substrate W. The indexer 3 collects the substrate W from the treating block 7.

In this specification, the direction in which the indexer 3 and the treating block 7 are arranged is called “front-rear direction X” for convenience. The front-rear direction X is horizontal. One direction of the front-rear direction X from the treating block 7 to the indexer 3 is called “forward direction”. The direction opposite to the forward direction is called “rearward direction”. The direction orthogonal to the front-rear direction X is called “transverse direction Y”. The transverse direction Y is horizontal. One direction in the “transverse direction Y” is called “rightward direction”, as appropriate. The direction opposite to the rightward direction is called “leftward direction”. When the front-rear direction X and the transverse direction Y are not distinguished, they are simply called “horizontal direction”. The perpendicular direction relative to the horizontal direction is called “vertical direction Z”. For reference, the drawings show front, rear, right, left, up, and down, as appropriate.

The indexer 3 includes a plurality of (e.g. four) carrier platforms 4. The carrier platforms 4 each include one carrier C placed thereon. The carrier C accommodates a plurality of substrates W. The carrier C is, for example, a front opening unified pod (FOUP), a standard mechanical interface (SMIF), or an open cassette (OC).

The indexer 3 includes a transport mechanism 5. The transport mechanism 5 is arranged rearward of the carrier platforms 4. The transport mechanism 5 transports the substrate W. The transport mechanism 5 is configured to access the carriers C placed on the carrier platforms 4.

The transport mechanism 5 includes a hand 5a and a hand driving unit 5b. The hand 5a supports the substrate W. The hand driving unit 5b is coupled to the hand 5a. The hand driving unit 5b moves the hand 5a. The hand driving unit 5b moves the hand 5a in the front-rear direction X, transverse direction Y, and vertical direction Z, for example. The hand driving unit 5b rotates the hand 5a in a horizontal plane, for example.

The treating block 7 includes a transport mechanism 8. The transport mechanism 8 transports the substrate W. The transport mechanism 8 is configured to receive the substrate W from the transport mechanism 5 and to deliver the substrate W to the transport mechanism 5.

The transport mechanism 8 includes a hand 8a and a hand driving unit 8b. The hand 8a supports the substrate W. The hand driving unit 8b is coupled to the hand 8a. The hand driving unit 8b moves the hand 8a. The hand driving unit 8b moves the hand 8a in the front-rear direction X, transverse direction Y, and vertical direction Z, for example. The hand driving unit 8b rotates the hand 8a in a horizontal plane, for example.

The treating block 7 includes a plurality of treating units 11. The treating units 11 are each arranged laterally of the transport mechanism 8. The treating units 11 each perform a treatment on the substrate W.

Each of the treating units 11 includes a substrate holder 13. The substrate holder 13 holds the substrate W.

The transport mechanism 8 is configured to access each of the treating units 11. The transport mechanism 8 is configured to deliver the substrate W to the substrate holder 13 and to take the substrate W from the substrate holder 13.

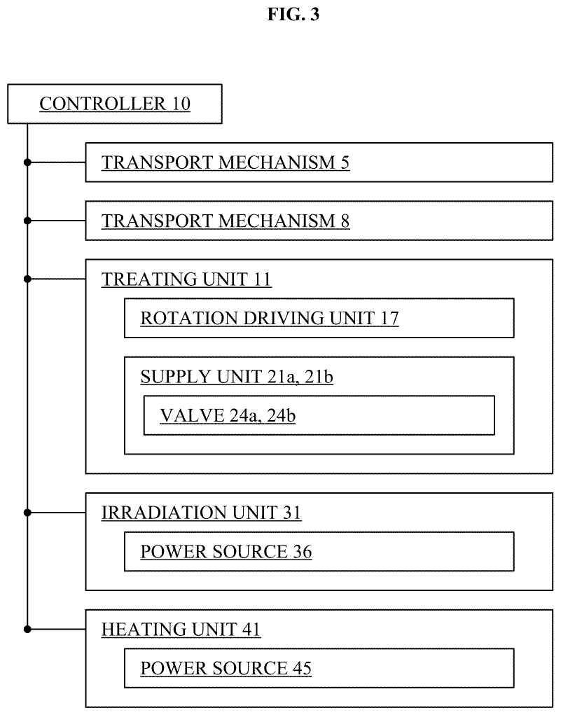

FIG. 3 is a control block diagram of the substrate treating apparatus 1. The substrate treating apparatus 1 includes a controller 10. The controller 10 is communicably connected to the transport mechanisms 5, 8 and the treating units 11. The controller 10 controls the transport mechanisms 5 and 8 and the treating units 11.

The controller 10 is implemented by a central processing unit (CPU) that performs various processes, a random-access memory (RAM) as a workspace of arithmetic processing, a storage medium such as a fixed disk. The controller 10 has various types of information stored in the storage medium in advance. The information included in the controller 10 includes transportation condition information and processing condition information, for example. The transportation condition information defines a condition related to the operation of the transport mechanisms 5 and 8. The processing condition information defines a condition related to the operation of the treating units 11. The processing condition information is also called as processing recipes.

An operation example of the substrate treating apparatus 1 will be simply described.

The indexer 3 supplies the substrate W to the treating block 7. Specifically, the transport mechanism 5 delivers the substrate W from each of the carriers C to the transport mechanism 8 of the treating block 7.

The transport mechanism 8 distributes the substrate W to each of the treating units 11. Specifically, the transport mechanism 8 transports the substrate W from the transport mechanism 5 to the substrate holders 13 of each of the treating units 11.

The treating unit 11 performs treatment on the substrate W held by the substrate holder 13. The treating unit 11 performs a dry treatment, for example, on the substrate W.

After the treating unit 11 performs treatment on the substrate W, the transport mechanism 8 collects the substrate W from each of the treating units 11. Specifically, the transport mechanism 8 receives the substrate W from each of the substrate holders 13. Then, the transport mechanism 8 delivers the substrate W to the transport mechanism 5.

The indexer 3 collects the substrate W from the treating block 7. Specifically, the transport mechanism 5 transports the substrate W from the transport mechanism 8 to the carrier C.

### 3. Construction of Treating Unit 11

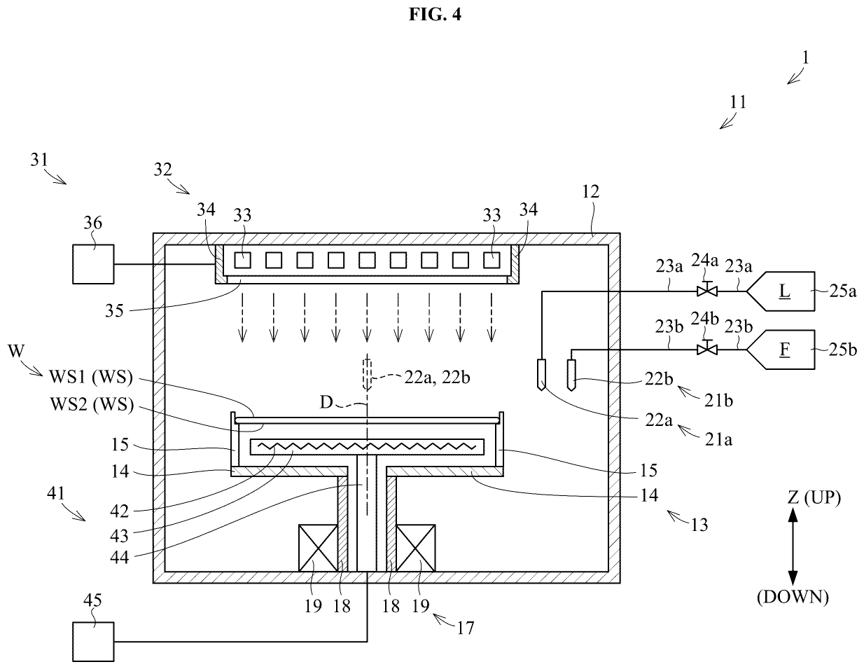

FIG. 4 is a diagram illustrating a construction of the treating unit 11. The treating units 11 each have the same structure. The treating unit 11 is classified as a single-wafer processing unit. That is, the treating units 11 each perform a treatment on only one substrate W at one time.

The treating unit 11 includes a casing 12. The casing 12 has a substantial box shape. The substrate W is treated in the interior of the casing 12.

The interior of the casing 12 is kept at normal pressure, for example. Accordingly, the substrate W is treated under an environment of normal pressure, for example. Here, the normal pressure includes standard atmospheric pressure (1 atm, 101325 Pa). The normal pressure falls within a pressure range of 0.7 to 1.3 atm, for example. In this specification, the value of pressure is indicated as absolute pressure relative to absolute vacuum.

The substrate holder 13 described above is installed the interior of the casing 12. The substrate holder 13 holds one substrate W. The substrate holder 13 holds the substrate W in a substantially horizontal posture.

The substrate holder 13 is located below the substrate W held by the substrate holder 13. The substrate holder 13 comes into contact with at least one of a lower surface WS2 of the substrate W or a peripheral edge of the substrate W. The substrate holder 13 is not in contact with an upper surface WS1 of the substrate W. Here, the upper surface WS1 is directed upward. The lower surface WS2 is directed downward. The upper surface WS1 is a part of the surface WS. The lower surface WS2 is another part of the surface WS. The lower surface WS2 is also called a back side of the substrate W.

A construction example of the substrate holder 13 will be described. The substrate holder 13 includes a support member 14. The support member 14 has a plate shape. The support member 14 extends in the horizontal direction. Although not illustrated, the support member 14 has substantially the same size as the substrate W in plan view: The support member 14 has an annular shape in plan view. The support member 14 forms an opening. The opening is located at the center of the support member 14 in plan view.

The substrate holder 13 includes a plurality of holding pins 15. The holding pins 15 are supported by the support member 14. The holding pins 15 are arranged on a peripheral edge of the support member 14. The holding pins 15 extend upward from the support member 14. Each of the holding pins 15 holds the substrate W. When the substrate W is held by the holding pins 15, the substrate W is located above the support member 14.

The treating units 11 each include a rotation driving unit 17. At least a part of the rotation driving unit 17 is installed in the interior of the casing 12. The rotation driving unit 17 is connected to the substrate holder 13. The rotation driving unit 17 rotates the substrate holder 13. The substrate W held by the substrate holder 13 rotates integrally with the substrate holder 13. The substrate W held by the substrate holder 13 rotates about a rotation axis D, for example. The rotation axis D passes through the center of the substrate W, for example. The rotation axis D extends in the vertical direction Z, for example.

A construction example of the rotation driving unit 17 will be described. The rotation driving unit 17 includes a shaft 18 and a motor 19. The shaft 18 is connected to the support member 14. The shaft 18 extends downward from the support member 14. The shaft 18 extends on the rotation axis D. The shaft 18 is a so-called hollow shaft. The shaft 18 has a tubular shape. The shaft 18 forms a hollow portion. The hollow portion is located in the interior of the shaft 18. The motor 19 is connected to the shaft 18. The motor 19 rotates the shaft 18 about the rotation axis D.

The treating unit 11 includes a supply unit 21a and a supply unit 21b. The supply unit 21a and the supply unit 21b each supply a liquid to the substrate W held by the substrate holder 13. The supply unit 21a and the supply unit 21b each supply a liquid to the upper surface WS1 of the substrate W held by the substrate holder 13. The supply unit 21a supplies a treatment liquid L. The treatment liquid L is used to treat the substrate W. The treatment liquid L is used to clean the substrate W, for example. The treatment liquid L is, for example, a cleaning liquid. The treatment liquid L is, for example, a rinse liquid.

The treatment liquid L is, for example, an organic solvent. The treatment liquid L is, for example, an alcohol. The treatment liquid L is, for example, isopropyl alcohol (IPA).

The treatment liquid L is, for example, deionized water. The treatment liquid L is, for example SC1. SC1 is a mixed liquid of ammonia, hydrogen peroxide, and deionized water.

A supply unit 21b supplies the dry assistant liquid F. The dry assistant liquid F is used to dry the substrate W. The dry assistant liquid F has a function of assisting drying of the substrate W. The dry assistant liquid F is a liquid. The dry assistant liquid F is a liquid at normal temperature.

The dry assistant liquid F contains an ultraviolet curable material. The ultraviolet curable material has an ultraviolet curable property. The ultraviolet curable material has not yet been cured by ultraviolet rays. The ultraviolet curable material has a property of being polymerized by ultraviolet rays. The ultraviolet curable material has a property of being cured by ultraviolet rays. The ultraviolet curable material has a property of being resinified by ultraviolet rays.

The ultraviolet curable material contains at least one of a monomer or an oligomer. At least one of the monomer or the oligomer in the ultraviolet curable material has a property of being polymerized by ultraviolet rays. The ultraviolet curable material does not include a polymer. The ultraviolet curable material does not include a macromolecule. The ultraviolet curable material does not include a polymer compound.

The ultraviolet curable material is a liquid. The ultraviolet curable material is a liquid at normal temperature.

The ultraviolet curable material is, for example, isobornyl acrylate. The ultraviolet curable material is, for example, an isobornyl acrylate monomer.

The dry assistant liquid F contains a polymerization initiator. The polymerization initiator may be called “photopolymerization initiator”. The polymerization initiator initiates polymerization of the ultraviolet curable material.

The polymerization initiator is, for example, a solid. The polymerization initiator is, for example, a solid at normal temperature. The polymerization initiator is, for example, a powder. The polymerization initiator in the dry assistant liquid F is dissolved in, for example, an ultraviolet curable material. The concentration of the polymerization initiator in the dry assistant liquid F is, for example, 1 wt % or more. The concentration of the polymerization initiator in the dry assistant liquid F is, for example, 10 wt % or less.

The polymerization initiator is, for example, 1-hydroxycyclohexyl phenyl ketone.

The dry assistant liquid F does not contain a solvent. The solvent is, for example, at least one of an organic solvent or deionized water. As described above, the ultraviolet curable material is a liquid. Accordingly, it is not necessary to dissolve the ultraviolet curable material in the solvent in order to produce the dry assistant liquid F. As described above, the polymerization initiator is dissolved in the ultraviolet curable material. Accordingly, it is not necessary to dissolve the polymerization initiator in the solvent in order to produce the dry assistant liquid F.

For example, the dry assistant liquid F is composed of only an ultraviolet curable material and a polymerization initiator.

The supply unit 21a includes a nozzle 22a. The nozzle 22a dispenses the treatment liquid L. The supply unit 21b includes a nozzle 22b. The nozzle 22b dispenses the dry assistant liquid F.

Each of the nozzles 22a and 22b is installed in the interior of the casing 12. Each of the nozzles 22a and 22b is movable to a standby position and a treatment position. In FIG. 4, the nozzles 22a and 22b located at the standby positions are indicated by solid lines. In FIG. 4, the nozzles 22a and 22b located at the treatment positions are indicated by broken lines. The standby position is, for example, a position deviated from above the substrate W held by the substrate holder 13. The treatment position is, for example, a position above the substrate W held by the substrate holder 13.

The dry assistant liquid F is used within a casing 12. As described above, the interior of the casing 12 is kept at normal pressure, for example. Accordingly, the dry assistant liquid F is used, for example, under an environment of normal pressure. The treatment liquid L is used in the interior of the casing 12. Accordingly, the treatment liquid L is also used, for example, under an environment of normal pressure.

The supply unit 21a includes a pipe 23a and a valve 24a. The pipe 23a is connected to the nozzle 22a. The valve 24a is provided on the pipe 23a. When the valve 24a opens, the nozzle 22a dispenses the treatment liquid L. When the valve 24a closes, the nozzle 22a does not dispense the treatment liquid L. Likewise, the supply unit 21b includes a pipe 23b and a valve 24b. The pipe 23b is connected to the nozzle 22b. The valve 24b is provided on the pipe 23b. A valve 24b controls dispensing of the dry assistant liquid F.

The supply unit 21a is connected to a supply source 25a. The supply source 25a is connected to, for example, the pipe 23a. The supply source 25a feeds the treatment liquid L to the supply unit 21a. Likewise, the supply unit 21b is connected to a supply source 25b. The supply source 25b is connected to, for example, the pipe 23b. A supply source 25b feeds the dry assistant liquid F to the supply unit 21b.

At least a part of the pipe 23a may be provided externally of the casing 12. The pipe 23b may also be arranged in a similar manner to the pipe 23a. The valve 24a may be provided externally of the casing 12. The valve 24b may also be arranged in a similar manner to the valve 24a. The supply source 25a may be provided externally of the casing 12. The supply source 25b may also be arranged in a similar manner to the supply source 25a.

The supply source 25a may supply the treatment liquid L to the plurality of treating units 11. Alternatively, the supply source 25a may supply the treatment liquid L to only one treating unit 11. The same applies to the supply source 25b.

The supply source 25a may be an element of the substrate treating apparatus 1. For example, the supply source 25a may be installed in the interior of the substrate treating apparatus 1. Alternatively, the supply source 25a need not be an element of the substrate treating apparatus 1. For example, the supply source 25a may be installed externally of the substrate treating apparatus 1. Likewise, the supply source 25b may be an element of the substrate treating apparatus 1. Alternatively, the supply source 25b need not be an element of the substrate treating apparatus 1.

The supply unit 21a may be called “treatment liquid supply unit”. The supply unit 21b may be called “dry assistant liquid supply unit”.

The treating unit 11 includes an irradiation unit 31. The irradiation unit 31 irradiates the substrate W held by the substrate holder 13 with ultraviolet rays. Specifically, the irradiation unit 31 irradiates an upper surface WS1 of the substrate W held by the substrate holder 13 with ultraviolet rays.

In FIG. 4, ultraviolet rays are schematically indicated by two-dot chain lines. The irradiation unit 31 emits ultraviolet rays downward. The ultraviolet irradiation region by the irradiation unit 31 is as large as or larger than the upper surface WS1 of the substrate W. The ultraviolet irradiation region by the irradiation unit 31 extends over the entire upper surface WS1 of the substrate W. The entire upper surface WS1 of the substrate W simultaneously receives the ultraviolet rays of the irradiation unit 31.

A construction example of the irradiation unit 31 will be described. The irradiation unit 31 includes a light emitting unit 32. The light emitting unit 32 is provided above the substrate holder 13. The light emitting unit 32 is provided above the substrate W held by the substrate holder 13. The light emitting unit 32 is installed in the interior of the casing 12, for example.

For example, the light emitting unit 32 does not move in the horizontal direction with respect to the substrate W held by the substrate holder 13. For example, the light emitting unit 32 does not move in the vertical direction Z with respect to the substrate W held by the substrate holder 13. For example, the light emitting unit 32 is fixed to the casing 12.

The light emitting unit 32 includes one or more light sources 33. Each of the light sources 33 generates ultraviolet rays. Each of the light sources 33 is, for example, a lamp. The lamp is, for example, a xenon lamp. Each of the light sources 33 is, for example, a light emitting diode (LED).

The light emitting unit 32 includes a housing 34. The housing 34 supports the light sources 33. The housing 34 has a substantial box shape. The housing 34 accommodates the light sources 33.

The light emitting unit 32 includes an emission surface 35. The emission surface 35 emits the ultraviolet rays from the light sources 33. The emission surface 35 emits ultraviolet rays downward. The emission surface 35 allows transmission of ultraviolet rays. The emission surface 35 is made of, for example, quartz glass. The emission surface 35 is disposed at the bottom of the housing 34, for example. The emission surface 35 is disposed above the substrate W held by the substrate holder 13. The emission surface 35 extends in the horizontal direction. The emission surface 35 overlaps with the entire substrate W held by the substrate holder 13 in plan view.

The irradiation unit 31 includes a power source 36. The power source 36 is electrically connected to the light emitting unit 32 (specifically, the light source 33). The power source 36 supplies electric power to the light emitting unit 32. The power source 36 controls the light emitting unit 32. The power source 36 switches the light emitting unit 32 between irradiation and non-irradiation of ultraviolet rays, for example. The power source 36 adjusts the intensity of ultraviolet rays, for example. The power source 36 adjusts, for example, an ultraviolet irradiation time.

The treating unit 11 includes a heating unit 41. The heating unit 41 heats the substrate W held by the substrate holder 13.

A construction example of the heating unit 41 will be described. The heating unit 41 includes a heater 42. The heater 42 generates heat. The heater 42 is, for example, a resistance heater. The heater 42 is, for example, an electric heater. The heater 42 includes, for example, a heating wire. The heater 42 is arranged below the substrate W held by the substrate holder 13. The heater 42 faces the lower surface WS2 of the substrate W held by the substrate holder 13. The heater 42 extends in the horizontal direction. The heating range heated by the heater 42 extends over the entire substrate W. The heater 42 uniformly heats the entire substrate W.

The heating unit 41 includes a support member 43 and a shaft 44. The support member 43 supports the heater 42. The support member 43 has a plate shape. The support member 43 extends in the horizontal direction. The support member 43 is located below the substrate W held by the substrate holder 13. The support member 43 is located above the support member 14. Although not illustrated, the support member 14 has substantially the same size as the substrate W in plan view. The shaft 44 is connected to the support member 43. The shaft 44 extends downward from the support member 43. The shaft 44 extends on the rotation axis D. The shaft 44 penetrates the opening of the support member 14. The shaft 44 is inserted into the hollow portion of the shaft 18. Even when the shaft 18 rotates, the shaft 44 does not rotate. Accordingly, the heater 42 and the support member 43 do not rotate either. The shaft 44 is fixed to the casing 12, for example.

The heating unit 41 includes a power source 45. The power source 45 is electrically connected to the heater 42. The power source 45 supplies electric power to the heater 42. The power source 45 controls the heater 42. The power source 45 switches the heater 42 between heating and non-heating, for example. The power source 45 adjusts an output of the heater 42, for example. The power source 45 adjusts, for example, a heating temperature by the heater 42. The power source 45 adjusts, for example, a heating time by the heater 42.

The treating unit 11 may further include a cup, not illustrated. The cup is installed in the interior of the casing 12. The cup is arranged laterally of the substrate holder 13. The cup surrounds an exterior of the substrate holder 13. The cup receives the liquid scattered from the substrate W held by the substrate holder 13.

Reference is made to FIG. 3. The controller 10 controls the rotation driving unit 17. The controller 10 controls the supply units 21a and 21b. The controller 10 controls the valves 24a and 24b. The controller 10 controls the irradiation unit 31. The controller 10 controls the power source 36. The controller 10 controls the heating unit 41. The controller 10 controls the power source 45.

### 4. Operation Example of Treating Unit 11

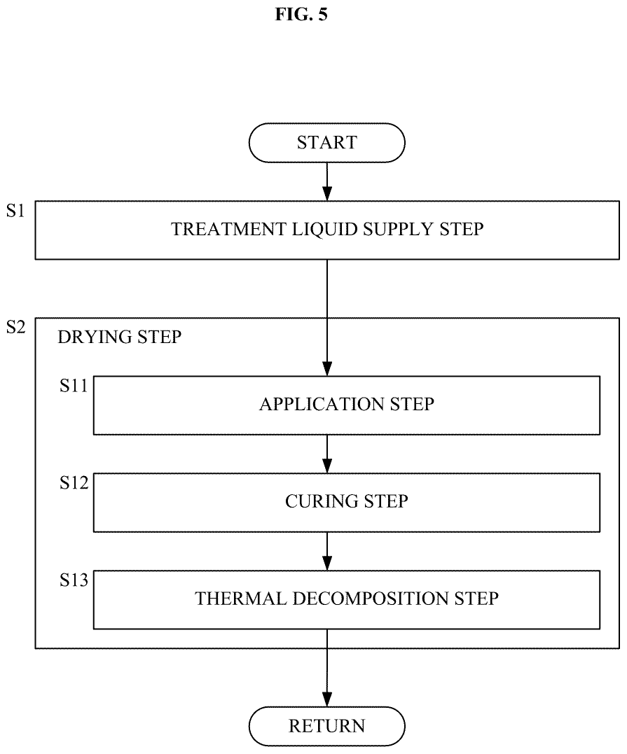

Reference is made to FIGS. 4 and 5. FIG. 5 is a flowchart showing procedures of a substrate treating method according to the embodiment. The substrate treating method includes a treatment liquid supply step and a drying step. The drying step is executed after the treatment liquid supply step. The drying step corresponds to the substrate drying method in the present invention. The treatment liquid supply step and the drying step are executed by the treating unit 11. The treating units 11 operate in accordance with control by the controller 10.

### Step S1: Treatment Liquid Supply Step

The treatment liquid L is supplied to the substrate W.

The substrate holder 13 holds the substrate W. The rotation driving unit 17 rotates the substrate holder 13. The supply unit 21a supplies the treatment liquid L to the substrate W held by the substrate holder 13. The irradiation unit 31 does not emit ultraviolet rays. The heating unit 41 does not heat the substrate W.

The substrate W is held in a substantially horizontal posture. The substrate W rotates integrally with the substrate holder 13. The treatment liquid L is supplied to the upper surface WS1 of the substrate W. Since the substrate W is rotating, the treatment liquid L smoothly spreads over the upper surface WS1. For example, the treatment liquid L cleans the substrate W.

Then, the supply unit 21a stops supplying the treatment liquid L to the substrate W.

In the treatment liquid supply step, the interior of the casing 12 is kept at normal temperature, for example. Accordingly, in the treatment liquid supply step, the substrate W is treated, for example, under an environment of normal temperature. The treatment liquid L is used under an environment of normal temperature. Here, the normal temperature includes room temperature. The normal temperature is, for example, a temperature within a range of 5° C. to 35° C. The normal temperature is, for example, a temperature within a range of 10° C. to 30° C. The normal temperature is, for example, a temperature within a range of 15° C. to 25° C.

At the end of the treatment liquid supply step, the treatment liquid L is present on the substrate W. The substrate W is in a wet state. The substrate W is not in a dried state.

### Step S2: Drying Step

The substrate W in a wet state is dried. The drying step includes an application step, a curing step, and a thermal decomposition step.

### Step S11: Application Step

The dry assistant liquid F is applied to the substrate W.

The substrate holder 13 holds the substrate W. The rotation driving unit 17 rotates the substrate holder 13 and the substrate W. The supply unit 21b supplies the dry assistant liquid F to the substrate W held by the substrate holder 13. The irradiation unit 31 does not emit ultraviolet rays. The heating unit 41 does not heat the substrate W.

The dry assistant liquid F is supplied to the upper surface WS1 of the substrate W. Since the substrate W is rotating, the dry assistant liquid F smoothly spreads over the upper surface WS1. The dry assistant liquid F is applied to the upper surface WS1. The upper surface WS1 is coated with the dry assistant liquid F. The dry assistant liquid F removes the treatment liquid L from the substrate W. The treatment liquid L on the substrate W is replaced with the dry assistant liquid F.

Then, the supply unit 21b stops supplying the dry assistant liquid F to the substrate W. The rotation driving unit 17 stops rotating the substrate holder 13 and the substrate W. The substrate W rests.

In the application step, the interior of the casing 12 is kept at normal temperature, for example. Accordingly, in the application step, the substrate W is treated, for example, under an environment of normal temperature. The dry assistant liquid F is applied to the substrate W, for example, under an environment of normal temperature.

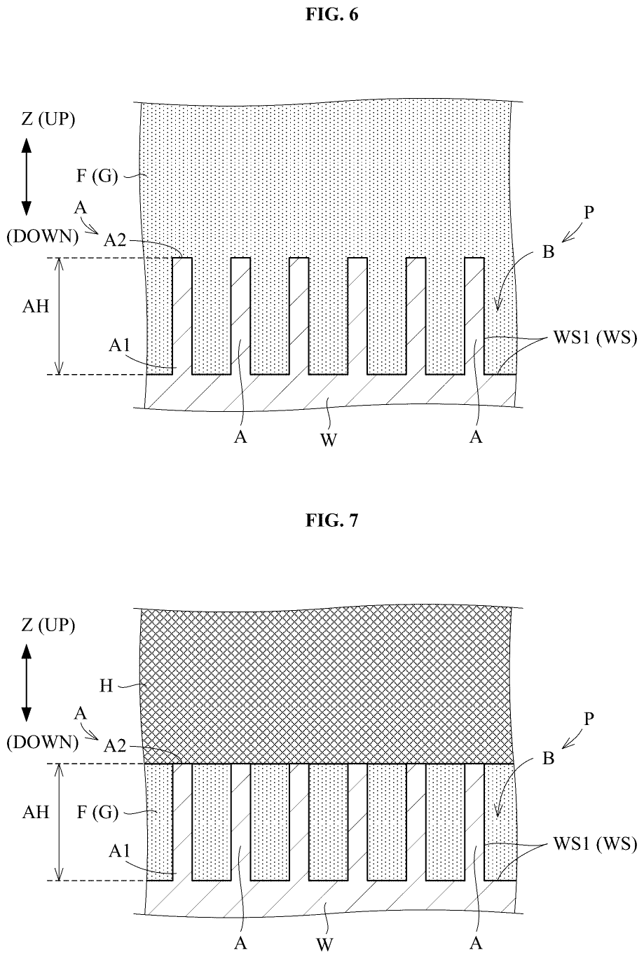

FIG. 6 is a view schematically illustrating the substrate W in the application step. The substrate W is in a posture with the pattern P facing upward. The pattern P is located on the upper surface WS1 of the substrate W. The pattern P is directed upward. The substrate W is held by the substrate holder 13. When the substrate W is held by the substrate holder 13, the pattern P is located on the upper surface WS1 of the substrate W. When the substrate W is held by the substrate holder 13, the pattern P is directed upward.

The dry assistant liquid F is present on the substrate W. The dry assistant liquid F is present on the upper surface WS1.

The dry assistant liquid F is applied to the pattern P. The pattern P is coated with the dry assistant liquid F. The pattern P comes into contact with the dry assistant liquid F. The projections A come into contact with the dry assistant liquid F.

The treatment liquid L has already been removed from the substrate W by the dry assistant liquid F. Accordingly, the treatment liquid L is not present on the substrate W. The treatment liquid L does not remain in the recesses B.

The dry assistant liquid F on the substrate W forms a liquid film G. The liquid film G is located on the substrate W. The liquid film G is located on the upper surface WS1. The liquid film G covers the upper surface WS1. The liquid film G covers the pattern P.

In the application step, the thickness of the liquid film G may be further adjusted. The thickness of the liquid film G is adjusted to, for example, a range of several hundred μm or less. The thickness of the liquid film G is adjusted to, for example, a range of several tens μm or more. For example, the thickness of the liquid film G may be adjusted while the supply unit 21b supplies the dry assistant liquid F to the substrate W. For example, the thickness of the liquid film G may be adjusted after the supply unit 21b stops supplying the dry assistant liquid F. For example, the thickness of the liquid film G may be adjusted by adjusting a rotation speed of the substrate W. For example, the thickness of the liquid film G may be adjusted by adjusting a period of rotation of the substrate W.

The thickness of the liquid film G is sufficiently larger than the height of the pattern P (specifically, the height AH of the projection A), for example. The thickness of the liquid film G is, for example, several tens of times or more the height of the pattern P.

The pattern P is entirely immersed in the liquid film G. The entire projections A is immersed in the liquid film G.

The pattern P is not in contact with a gas. The pattern P is not in contact with a gas-liquid interface. Accordingly, a capillary force does not act on the pattern P. The capillary force is, for example, a surface tension of the dry assistant liquid F. The projection A is not in contact with a gas. The projection A is not in contact with a gas-liquid interface. Accordingly, a capillary force does not act on the projection A. The capillary force is, for example, a surface tension of the dry assistant liquid F.

The recess B is filled with the liquid film G. The recess B is entirely filled with only the liquid film G.

### Step S12: Curing Step

The dry assistant liquid F on the substrate W is irradiated with ultraviolet rays. A solidified film is formed on the substrate W.

The substrate holder 13 holds the substrate W. The irradiation unit 31 irradiates the substrate W held by the substrate holder 13 with ultraviolet rays. The rotation driving unit 17 does not rotate the substrate holder 13 and the substrate W. The heating unit 41 does not heat the substrate W.

In the curing step, the interior of the casing 12 is kept at normal temperature, for example. Accordingly, in the curing step, the substrate W is treated, for example, under an environment of normal temperature. The solidified film is formed, for example, under an environment of normal temperature.

FIG. 7 is a view schematically illustrating the substrate W in the curing step. The substrate W is in a posture with the pattern P facing upward. The pattern P is located on the upper surface WS1 of the substrate W. The pattern P is directed upward.

The upper surface WS1 of the substrate W is exposed to ultraviolet rays. The dry assistant liquid F on the substrate W is exposed to ultraviolet rays. The polymerization initiator of the dry assistant liquid F generates active species. The active species is, for example, a radical. The active species initiates a polymerization reaction of the ultraviolet curable material of the dry assistant liquid F. As the polymerization reaction of the ultraviolet curable material proceeds, the degree of polymerization of the ultraviolet curable material increases. The fluidity of the dry assistant liquid F on the substrate W decreases. The dry assistant liquid F on the substrate W becomes hard. The dry assistant liquid F on the substrate W is cured.

Eventually, the ultraviolet curable material becomes a polymer. The polymer of the ultraviolet curable material corresponds to a cured product of the ultraviolet curable material. The polymer of the ultraviolet curable material corresponds to a macromolecule. The polymer of the ultraviolet curable material corresponds to a polymer compound.

The polymer of the ultraviolet curable material forms the solidified film H. The solidified film H contains the polymer of the ultraviolet curable material.

In other words, the dry assistant liquid F is changed into the solidified film H by the polymerization reaction of the ultraviolet curable material. The liquid film G is changed to the solidified film H by the polymerization reaction. The dry assistant liquid F decreases due to the polymerization reaction. The polymerization reaction causes the liquid film G to become thinner.

The solidified film H is a solid. The solidified film H is a solid at normal temperature. The solidified film H may be called “cured film”. The solidified film H may be called “resin film”.

For example, the solidified film H has substantially no elasticity. For example, the solidified film H is not substantially deformed. Alternatively, the solidified film H may have elasticity.

The solidified film H has thermal decomposability.

The solidified film H has a thermal decomposition temperature higher than normal temperature. The thermal decomposition temperature of the solidified film H is higher than the boiling point of the dry assistant liquid F. The boiling point of the dry assistant liquid F is higher than normal temperature. The thermal decomposition temperature of the solidified film H is higher than the boiling point of the ultraviolet curable material. The boiling point of the ultraviolet curable material is higher than normal temperature. The thermal decomposition temperature of the solidified film H is, for example, 100 degrees or higher. The thermal decomposition temperature of the solidified film H is, for example, 200 degrees or higher. The thermal decomposition temperature of the solidified film H is, for example, 400 degrees or higher. The thermal decomposition temperature of the solidified film H is, for example, 700 degrees or higher.

The solidified film H is formed on the substrate W. The solidified film H is formed on the upper surface WS1. The solidified film H is formed above the pattern P.

The solidified film H covers the upper surface WS1. The solidified film H covers the pattern P.

The dry assistant liquid F remains in the recess B.

The solidified film H has a thickness. The thickness of the solidified film H is sufficiently larger than the height of the pattern P (specifically, the height AH of the projection A). The thickness of the solidified film H is, for example, several tens of times or more the height of the pattern P.

The thickness of the solidified film H is not excessively large. The thickness of the solidified film H is, for example, several hundred μm or less.

The tip section of the pattern P (specifically, the tip section A2 of the projection A) comes into contact with the solidified film H. The tip section of the pattern P is connected to the solidified film H. The tip section of the pattern P is adhered to the solidified film H, for example. The tip section of the pattern P is linked to the solidified film H, for example. The solidified film H bridges a plurality of tip sections of the pattern P. The solidified film H corresponds to a bridge connecting the tip sections of the pattern P. Accordingly, the pattern P (specifically, the projections A) is suitably supported by the solidified film H.

The base end section of the pattern P (specifically, the base end section A1 of the projection A) comes into contact with the dry assistant liquid F. The base end section of the pattern P does not come into contact with the solidified film H. Even when the base end section of the pattern P does not come into contact with the solidified film H, the pattern P is suitably supported by the solidified film H.

For example, at the end of the curing step, a part of the dry assistant liquid F may remain on the substrate W. Alternatively, at the end of the curing step, the dry assistant liquid F may entirely disappear from the substrate W.

A case where a part of the dry assistant liquid F remains on the substrate W at the end of the curing step is called “Case 1”. A case where the dry assistant liquid F entirely disappears from the substrate W at the end of the curing step is called “Case 2”.

Case 1 will be described. FIG. 7 corresponds to a schematic view of the substrate W at the end of the curing step of Case 1. In Case 1, only a part of the pattern P comes into contact with the solidified film H. In Case 1, only a part of the projection A comes into contact with the solidified film H.

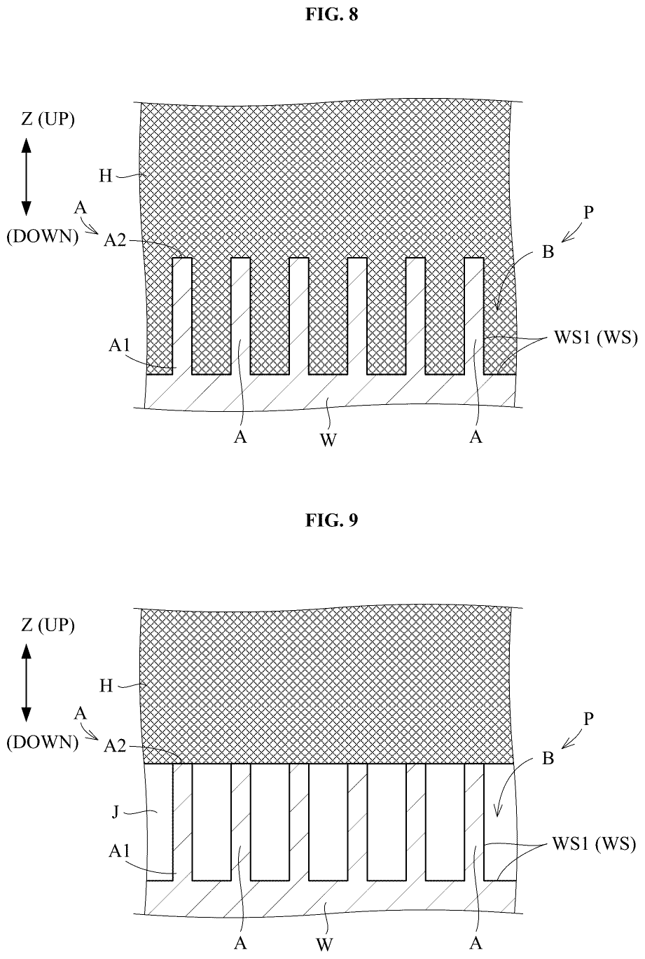

Case 2 will be described. FIG. 8 is a view schematically illustrating the substrate W in the curing step. FIG. 8 corresponds to a schematic view of the substrate W at the end of the curing step in Case 2. The solidified film H further grows on the substrate W. The solidified film H extends downward in the recess B, for example. The dry assistant liquid F on the substrate W further decreases. The liquid film G further becomes thinner.

Eventually, the dry assistant liquid F entirely disappears from the substrate W. The entire dry assistant liquid F changes to, for example, the solidified film H. The liquid film G entirely disappears from the substrate W. The liquid is not present on the substrate W. The pattern P is not in contact with the liquid. The projection A is not in contact with the liquid.

The recess B is filled with the solidified film H. The recesses B are entirely filled with only the solidified film H.

The pattern P entirely comes into contact with the solidified film H. The pattern P is entirely connected to the solidified film H. The entire pattern P is adhered to the solidified film H, for example. The entire pattern P is linked to the solidified film H, for example. Accordingly, the pattern P is more suitably supported by the solidified film H.

The entire projection A comes into contact with the solidified film H. The entire projection A is connected to the solidified film H. The entire projection A is adhered to the solidified film H, for example. The entire projection A is linked to the solidified film H, for example. Accordingly, the projection A is more suitably supported by the solidified film H.

### Step S13: Thermal Decomposition Step

The solidified film H on the substrate W is heated. The solidified film H is decomposed by heat. The substrate W is dried.

The substrate holder 13 holds the substrate W. The heating unit 41 heats the substrate W held by the substrate holder 13. The rotation driving unit 17 does not rotate the substrate holder 13 and the substrate W. The irradiation unit 31 does not emit ultraviolet rays.

The solidified film H is heated through the substrate W held by the substrate holder 13. The temperature of the solidified film H rises from normal temperature, for example. The temperature of the solidified film H rises to, for example, a temperature equal to or higher than the thermal decomposition temperature of the solidified film H.

The solidified film H is heated at a temperature equal to or higher than the thermal decomposition temperature of the solidified film H. For example, the solidified film H is heated at a temperature of 100 degrees or higher. For example, the solidified film H is heated at a temperature of 200 degrees or higher. For example, the solidified film H is heated at a temperature of 400 degrees or higher. For example, the solidified film H is heated at a temperature of 700 degrees or higher.

The thermal decomposition step in Case 1 will be specifically described. In Case 1, as shown in FIG. 7, a part of the dry assistant liquid F remains on the substrate W at the end of the curing step.

FIG. 9 is a view schematically illustrating the substrate W in the thermal decomposition step. The boiling point of the dry assistant liquid F is lower than the thermal decomposition temperature of the solidified film H. Accordingly, the dry assistant liquid F evaporates prior to the thermal decomposition of the solidified film H. The dry assistant liquid F remaining on the substrate W at the end of the curing step evaporates. The dry assistant liquid F remaining on the substrate W at the end of the curing step evaporates without being changed to the solidified film H.

When the dry assistant liquid F evaporates, the solidified film H is not substantially thermally decomposed. When the dry assistant liquid F evaporates, the solidified film H supports the pattern P. When the dry assistant liquid F evaporates, the solidified film H supports the projections A. That is, when the dry assistant liquid F evaporates, the pattern P is protected by the solidified film H. When the dry assistant liquid F evaporates, the projections A are protected by the solidified film H. Thus, when the dry assistant liquid F evaporates, the pattern P does not collapse. When the dry assistant liquid F evaporates, the projections A do not collapse.

When the dry assistant liquid F evaporates in the thermal decomposition step, the pattern P may come into contact with the gas-liquid interface between the dry assistant liquid F and the gas. When the pattern P comes into contact with the gas-liquid interface, the capillary force of the dry assistant liquid F acts on the pattern P. However, when the dry assistant liquid F evaporates in the thermal decomposition step, the pattern P is supported by the solidified film H. Accordingly, even when the capillary force acts on the pattern P in the thermal decomposition step, the solidified film H prevents the pattern P from collapsing. Thus, even when the capillary force acts on the pattern P in the thermal decomposition step, the pattern P does not collapse.

Eventually, the dry assistant liquid F is removed from the substrate W. The dry assistant liquid F is removed from the substrate W without being changed to the solidified film H. The dry assistant liquid F disappears from the substrate W. A gas J in the casing 12 enters the recess B. The solidified film H protects the pattern P until the dry assistant liquid F entirely disappears from the substrate W. The solidified film H protects the projections A until the dry assistant liquid F entirely disappears from the substrate W.

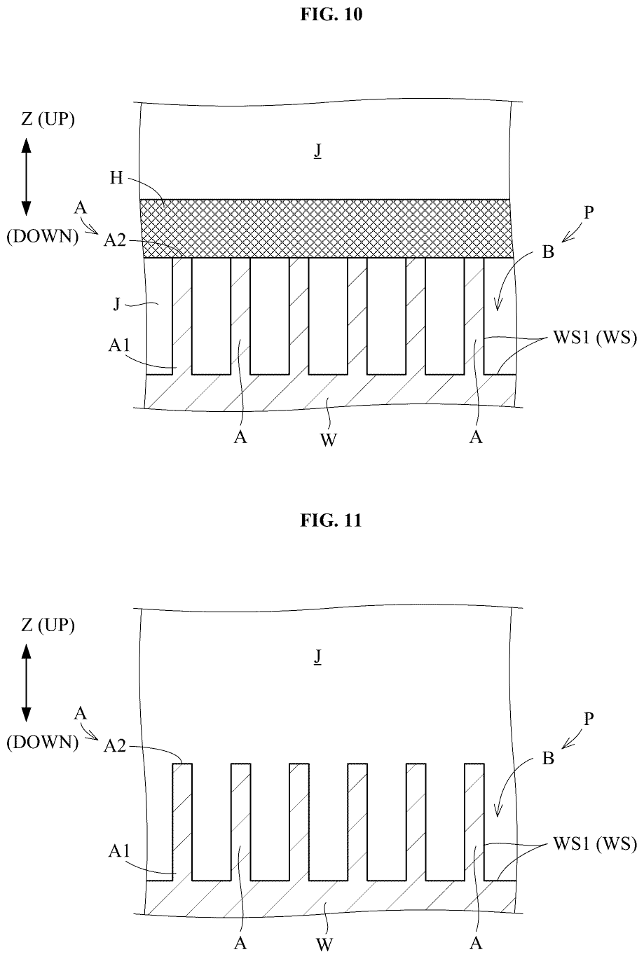

FIG. 10 is a view schematically illustrating the substrate W in the thermal decomposition step. After the dry assistant liquid F is removed from the substrate W, the solidified film H is thermally decomposed. The solidified film H gradually decreases. The solidified film H gradually becomes thinner. The solidified film H is gradually removed from the substrate W. The solidified film H gradually disappears from the substrate W.

Specifically, the polymer of the ultraviolet curable material in the solidified film H is thermally decomposed. The polymer of the ultraviolet curable material is depolymerized. The molecular weight of the polymer of the ultraviolet curable material decreases.

For example, the solidified film H is gasified. For example, the polymer of the ultraviolet curable material is gasified.

For example, the solidified film H is decomposed into a plurality of particles. For example, the polymer of the ultraviolet curable material is decomposed into a plurality of particles. The plurality of particles floats from the substrate W. The floating particles form, for example, smoke.

For example, the solidified film H is removed from the substrate W without being melted. For example, the polymer of the ultraviolet curable material is removed from the substrate W without being melted.

When the solidified film H is thermally decomposed, the solidified film H does not apply a significant force on the pattern P. When the solidified film H is thermally decomposed, the force acting on the pattern P is low.

When the solidified film H is thermally decomposed, the solidified film H does not apply a significant force to the projection A. When the solidified film H is thermally decomposed, the force acting on the projection A is low.

FIG. 11 is a view schematically illustrating the substrate W in the thermal decomposition step. Finally, the solidified film H is entirely removed from the substrate W. The upper surface WS1 of the substrate W is exposed to the gas J. The pattern P is entirely exposed to the gas J. The entire projection A is exposed to the gas J. The entire recess B is filled with only the gas J. The liquid is not present on the substrate W. The substrate W is dried. The drying step is completed.

The thermal decomposition step in Case 2 will be described. In Case 2, as shown in FIG. 8, the dry assistant liquid F entirely disappears from the substrate W at the end of the curing step.

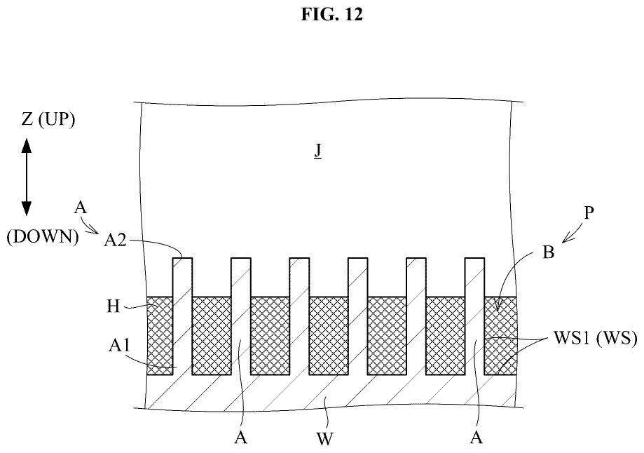

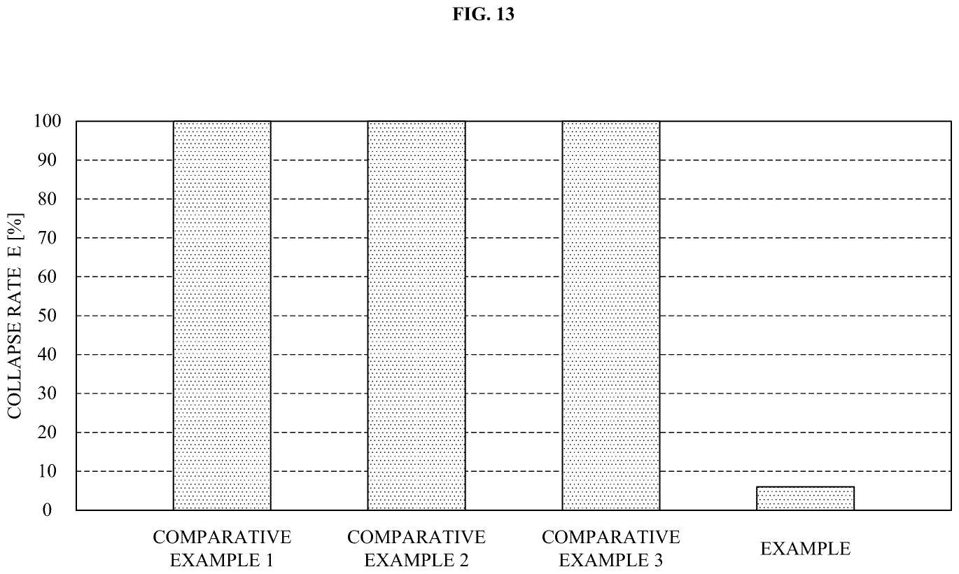

FIG. 12 is a view schematically illustrating the substrate W in the thermal decomposition step. The solidified film H is thermally decomposed. The solidified film H gradually decreases. The solidified film H gradually becomes thinner. The solidified film H is gradually removed from the substrate W. The solidified film H gradually disappears from the substrate W.

For convenience, reference is made to FIG. 11. Finally, the solidified film H is entirely removed from the substrate W. The substrate W is dried. The drying step is completed.

### 5. Technical Significance of Dry Treatment Method

Technical significance of the dry treatment method of the embodiment will be described with reference to Example and Comparative Examples 1 to 3.

Conditions of Example will be described. In Example, a series of treatments including the application step, the curing step, and the thermal decomposition step is performed on the substrate W.

In the application step, the dry assistant liquid F is composed of only an isobornyl acrylate monomer and 1-hydroxycyclohexyl phenyl ketone. The isobornyl acrylate monomer corresponds to an ultraviolet curable material. 1-hydroxycyclohexyl phenyl ketone corresponds to a polymerization initiator. The mass ratio of the polymerization initiator and the ultraviolet curable material is as follows.

Polymerization initiator:ultraviolet curable material=4:100 (mass ratio)

In the curing step, ultraviolet rays have a wavelength of 365 nm. Ultraviolet rays have an intensity of 342 mW/cm². The dry assistant liquid F on the substrate W is irradiated with ultraviolet rays for 10 minutes.

In the thermal decomposition step, the substrate W and the solidified film H are heated at 700 degrees. The substrate W and the solidified film H are heated for one hour.

Conditions of Comparative Example 1 will be described. In Comparative Example 1, a series of treatments including a first liquid supply step and a spin drying step is performed on the substrate W. In the first liquid supply step, deionized water is supplied to the substrate W. In the spin drying step, deionized water on the substrate W is shaken off by rotating the substrate W, and thus the substrate W is dried.

Conditions of Comparative Example 2 will be described. In Comparative Example 2, a series of treatments including a second liquid supply step and a spin drying step is performed on the substrate W. In the second liquid supply step, isopropyl alcohol is supplied to the substrate W. In the spin drying step, isopropyl alcohol on the substrate W is shaken off by rotating the substrate W, and thus the substrate W is dried.

Conditions of Comparative Example 3 will be described. In Comparative Example 3, a series of treatments including a third liquid supply step, a solidification step, and a sublimation step is performed on the substrate W. In the third liquid supply step, a liquid of tert-butanol is supplied to the substrate W. The liquid of tert-butanol is composed of only tert-butanol. The liquid of tert-butanol does not contain substances other than tert-butanol (e.g. a solvent). In the solidification step, the substrate W is cooled. In the solidification step, the tert-butanol is solidified on the substrate W. In the solidification step, a solid of tert-butanol is formed on the substrate W. In the sublimation step, a chamber accommodating the substrate W is evacuated. In the sublimation step, the atmospheric pressure of the chamber is lower than normal pressure. In the sublimation step, the solid of tert-butanol on the substrate W is sublimated. In the sublimation step, the tert-butanol changes from a solid to a gas without passing through a liquid phase. The tert-butanol is sublimated, and thus the substrate W is dried.

The substrate W treated in Example and the substrates W treated in Comparative Examples 1 to 3 were evaluated by a collapse rate E.

The collapse rate E is obtained as follows. An observer observes the pattern P in one or more local areas. Each local area is a minute region of the substrate W. Each local area is magnified 50.000 times, for example, by a scanning electron microscope. The observer observes the projections A in each local area one by one. The observer classifies each of the projections A into either a collapsed projection A or a non-collapsed projection A. The number of observed projections A is defined as NA. The number of collapsed projections A is defined as NB. The number NB is equal to or less than the number NA. The collapse rate E is a ratio of the number NB to the number NA. The collapse rate E is defined by, for example, the following equation.

$$E = NB / NA * 100 ( \% )$$

FIG. 13 is a graph showing evaluation of the substrates W treated according to Example and the substrates W treated according to Comparative Examples 1 to 3. Specifically. FIG. 13 shows the collapse rate E in Example and the collapse rates E in Comparative Examples 1 to 3.

The collapse rate E of Example was less than 10%. The collapse rate E of Example was several %. The collapse rate E of Comparative Example 1 was 100%. The collapse rate E of each of Comparative Examples 2 and 3 was also 100%. The following is found from FIG. 13. In Example, collapse of the pattern P is suitably suppressed. In Example, the pattern P is suitably protected as compared with Comparative Examples 1 to 3. In Example, the substrate W is dried with the pattern P suitably protected.

In Comparative Example 1, the entire pattern P was collapsed. The reason for this is presumed to be that the capillary force of the deionized water acted on the pattern P in the spin drying step.

In Comparative Example 2, the entire pattern P was collapsed. The reason for this is presumed to be that the capillary force of isopropyl alcohol acted on the pattern P in the spin drying step.

In Comparative Example 3, no liquid is present on the substrate W in the sublimation step. Thus, in the sublimation step, the capillary force does not act on the pattern P. However, in Comparative Example 3, the entire pattern P was collapsed. Comparative Example 3 shows that the pattern P may collapse even when the liquid is not present on the substrate W in the sublimation step. Comparative Example 3 shows that, even in a case where the capillary force does not act on the pattern P when the solid is removed from the substrate W, the pattern P may collapse.

### 6. Effects of Embodiment

The substrate drying method is to dry the substrate W on which the pattern P is formed. The substrate drying method includes an application step, a curing step, and a thermal decomposition step. In the application step, the dry assistant liquid F is applied to the substrate W. The dry assistant liquid F contains an ultraviolet curable material. In the curing step, the dry assistant liquid F on the substrate W is irradiated with ultraviolet rays. In the curing step, the solidified film H is formed on the substrate W. In the thermal decomposition step, the solidified film H on the substrate W is heated, and thus the solidified film H is thermally decomposed. In the thermal decomposition step, the substrate W is dried.

As described above, the substrate drying method includes the application step and the curing step. Accordingly, the solidified film H is suitably formed on the substrate W. Further, the solidified film H suitably supports the pattern P of the substrate W. The substrate drying method further includes a thermal decomposition step. Accordingly, the solidified film H is suitably decomposed by heat. Thus, the solidified film H is suitably removed from the substrate W. Specifically, the solidified film H is removed from the substrate W without applying a significant force to the pattern P. Therefore, the substrate W is dried in a state where the pattern P is protected. As described above, according to the substrate drying method, the substrate W is appropriately dried.

The solidified film H has thermal decomposability. Accordingly, in the thermal decomposition step, the solidified film H is suitably thermally decomposed. Thus, the substrate W is more appropriately dried.

In the thermal decomposition step, the solidified film H is heated at a temperature equal to or higher than the thermal decomposition temperature of the solidified film H. Accordingly, in the thermal decomposition step, the solidified film H is thermally decomposed, more suitably. Thus, the substrate W is more appropriately dried.

In the thermal decomposition step, the solidified film H is heated at a temperature of 700 degrees or higher. Accordingly, it is easy to set the heating temperature of the solidified film H to be equal to or higher than the thermal decomposition temperature of the solidified film H.

In the thermal decomposition step, the solidified film H is thermally decomposed, and thus the solidified film H is removed from the substrate W. Accordingly, the solidified film H does not remain on the substrate W after the thermal decomposition step. After the thermal decomposition step, the residue of the solidified film H does not remain on the substrate W. Thus, a clean substrate W is obtained after the thermal decomposition step. Therefore, the substrate W is more appropriately dried.

In the thermal decomposition step, the solidified film H is gasified. Accordingly, in the thermal decomposition step, the solidified film H is suitably removed from the substrate W.

In the thermal decomposition step, the solidified film H is decomposed into a plurality of particles. In the thermal decomposition step, the particles float from the substrate W. Accordingly, in the thermal decomposition step, the solidified film H is suitably removed from the substrate W.

In the thermal decomposition step, the solidified film H is removed from the substrate W without being melted. Accordingly, when the solidified film H is thermally decomposed, the force acting on the pattern P is even lower. Thus, even when the solidified film H is thermally decomposed, the pattern P is suitably protected. In the curing step, the ultraviolet curable material becomes a polymer. The solidified film H contains the polymer of the ultraviolet curable material. Accordingly, in the curing step, the solidified film H is suitably formed.

In the thermal decomposition step, the polymer of the ultraviolet curable material is thermally decomposed. In other words, in the thermal decomposition step, the polymer of the ultraviolet curable material is depolymerized. In the thermal decomposition step, the molecular weight of the polymer of the ultraviolet curable material decreases. Thus, in the thermal decomposition step, the solidified film H is suitably thermally decomposed.

The ultraviolet curable material is a liquid. Accordingly, it is easy to obtain the dry assistant liquid F from the ultraviolet curable material. For example, it is not necessary to use a solvent in order to obtain the dry assistant liquid F. For example, the dry assistant liquid F can be obtained without using a solvent.

The ultraviolet curable material does not include a polymer. Accordingly, it is easy to obtain a liquid of the ultraviolet curable material.

The ultraviolet curable material is isobornyl acrylate. As described in Example, when the ultraviolet curable material is isobornyl acrylate, the pattern P is more suitably protected. Thus, the substrate W is more appropriately dried.

The ultraviolet curable material is an isobornyl acrylate monomer. Accordingly, the substrate W is more appropriately dried. Furthermore, it is easier to obtain a liquid of the ultraviolet curable material.

The dry assistant liquid F does not contain a solvent. Accordingly, in the application step, the solvent is not applied to the substrate W. In the curing step and the thermal decomposition step, the solvent is not present on the substrate W. Thus, in the curing step and the thermal decomposition step, the capillary force of the solvent does not act on the pattern P. That is, in the curing step and the thermal decomposition step, the force acting on the pattern P is further reduced. Therefore, it is easier to protect the pattern P in the curing step and the thermal decomposition step.

The dry assistant liquid F further contains a polymerization initiator. The polymerization initiator promotes polymerization of the ultraviolet curable material. Thus, in the curing step, the solidified film H is rapidly formed.

At the end of the curing step of Case 1, a part of the dry assistant liquid F remains on the substrate W. In the thermal decomposition step, the dry assistant liquid F remaining on the substrate W at the end of the curing step is evaporated. Accordingly, even when a part of the dry assistant liquid F remains on the substrate W in the curing step, the substrate W is appropriately dried in the thermal decomposition step.

The boiling point of the dry assistant liquid F is lower than the thermal decomposition temperature of the solidified film H. Accordingly, in the thermal decomposition step of Case 1, the dry assistant liquid F evaporates, and then the solidified film H is thermally decomposed. In other words, in the thermal decomposition step in Case 1, the solidified film H is not substantially thermally decomposed until the dry assistant liquid F evaporates. Thus, in the thermal decomposition step of Case 1, the pattern P is protected by the solidified film H until the dry assistant liquid F evaporates. Specifically, in the thermal decomposition step of Case 1, the pattern P is supported by the solidified film H until the dry assistant liquid F evaporates. Therefore, even in Case 1, the substrate W is appropriately dried. The boiling point of the ultraviolet curable material is lower than the thermal decomposition temperature of the solidified film H. Accordingly, in the thermal decomposition step, the dry assistant liquid F suitably evaporates before the solidified film H is thermally decomposed.

At the end of the curing step of Case 2, the dry assistant liquid F entirely disappears from the substrate W. For example, at the end of the curing step of Case 2, the entire dry assistant liquid F changes to the solidified film H. Accordingly, in the thermal decomposition step of Case 2, the dry assistant liquid F is not present on the substrate W. Thus, in the thermal decomposition step of Case 2, the capillary force of the dry assistant liquid F does not act on the pattern P. That is, in the thermal decomposition step of Case 2, the force acting on the pattern P is further reduced. Therefore, it is easier to protect the pattern P in the thermal decomposition step of Case 2.

The irradiation region of the irradiation unit 31 extends over the entire substrate W. Accordingly, the entire dry assistant liquid F on the substrate W can be uniformly irradiated with ultraviolet rays. Thus, the solidified film H is uniformly formed over the entire substrate W. The solidified film H is uniformly formed over the entire upper surface WS1. Furthermore, the entire dry assistant liquid F on the substrate W is simultaneously exposed to ultraviolet rays. Accordingly, in the curing step, the solidified film H is rapidly formed. Thus, the time of the curing step is suitably shortened.

In the application step, the dry assistant liquid F on the substrate W forms the liquid film G. The liquid film G has a thickness sufficiently larger than the height of the pattern P. The pattern P is entirely immersed in the liquid film G. Accordingly, in the application step, the pattern P does not come into contact with the gas-liquid interface. Thus, in the application step, the capillary force of the dry assistant liquid F does not act on the pattern P. Therefore, also in the application step, the pattern P is suitably protected. Also in the application step, the pattern P is suitably prevented from collapsing.

The thickness of the solidified film H is not excessively large. For example, the thickness of the solidified film H is several hundred μm or less. Thus, in the thermal decomposition step, the solidified film H is rapidly thermally decomposed. The time of the thermal decomposition step is suitably shortened.

In the application step, the thickness of the liquid film G is adjusted. In the curing step, at least a part of the liquid film G changes to the solidified film H. Accordingly, the thickness of the solidified film H is suitably adjusted.

The substrate treating method is to treat a substrate W on which a pattern P is formed. The substrate treating method includes a treatment liquid supply step and a drying step. In the treatment liquid supply step, the treatment liquid L is supplied to the substrate W. In the drying step, the above-described substrate drying method is executed. Specifically, the drying step includes an application step, a curing step, and a thermal decomposition step. Thus, the substrate W is dried in a state where the pattern P is protected.

As described above, according to the substrate treating method, the substrate W is appropriately treated.

In the application step, the treatment liquid L is removed from the substrate W. Accordingly, in the curing step and the thermal decomposition step, the treatment liquid L is not present on the substrate W. Thus, it is easier to protect the pattern P in the curing step and the thermal decomposition step.

### 7. Modified Embodiment

The present invention is not limited to the embodiment, and can be modified as follows.

(1) In the embodiment described above, the dry assistant liquid F contains a polymerization initiator. However, the present invention is not limited thereto. For example, the dry assistant liquid F need not contain a polymerization initiator. For example, when the ultraviolet curable material initiates polymerization without a polymerization initiator, the dry assistant liquid F does not need to contain a polymerization initiator. For example, the dry assistant liquid F is composed of only an ultraviolet curable material.

(2) In the thermal decomposition step according to the embodiment described above, the temperature rise curve of the solidified film H may be selected and changed, as appropriate. Hereinafter, two modified embodiments will be described.

(2-1) In the thermal decomposition step, the temperature of the solidified film H continuously rises. According to the modified embodiment, it is easy to rapidly increase the temperature of the solidified film H. Accordingly, the solidified film H is thermally decomposed more rapidly. Thus, the time of the thermal decomposition step is effectively shortened. Therefore, the substrate W is efficiently dried.

(2-2) In the thermal decomposition step, the temperature of the solidified film H stepwise rises.

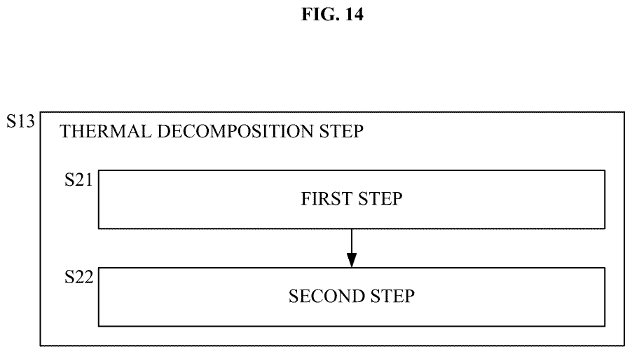

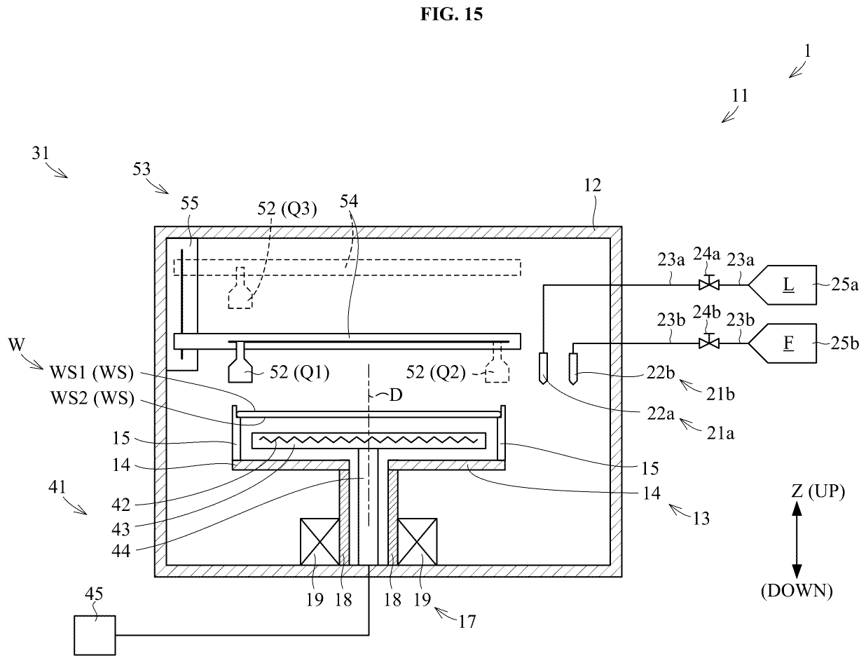

FIG. 14 is a flowchart showing procedures of a thermal decomposition step according to a modified embodiment. Specifically, the thermal decomposition step includes a first step (Step S21) and a second step (Step S22).

In the first step, the substrate W is heated at the first temperature. In the first step, for example, the temperature of the substrate W rises from normal temperature to the first temperature. In the first step, for example, the temperature of the solidified film H also rises from normal temperature to the first temperature. The first temperature is lower than the thermal decomposition temperature of the solidified film H. The first temperature is equal to or higher than the boiling point of the dry assistant liquid F. The first temperature is equal to or higher than the boiling point of the ultraviolet curable material.

The second step is executed after the first step. In the second step, the solidified film H is heated at the second temperature. The second temperature is higher than the first temperature. The second temperature is equal to or higher than the thermal decomposition temperature of the solidified film H. In the second step, for example, the temperature of the solidified film H rises from the first temperature to the second temperature.

In the modified embodiment, in the first step, the dry assistant liquid F is reliably evaporated from the substrate W. In the first step, the dry assistant liquid F is reliably removed from the substrate W. Even when a part of the dry assistant liquid F remains on the substrate W at the end of the curing step, the entire dry assistant liquid F remaining on the substrate W is removed from the substrate W in the first step. The entire dry assistant liquid F remaining on the substrate W at the end of the curing step is removed from the substrate W without being changed to the solidified film H. Accordingly, in the second step, the dry assistant liquid F is not present on the substrate W. Therefore, it is easier to protect the pattern P in the second step.

The first temperature is lower than the second temperature. Thus, in the first step, thermal decomposition of the solidified film H is suitably prevented. Therefore, in the first step, the pattern P is suitably protected by the solidified film H.

The first temperature is lower than the thermal decomposition temperature of the solidified film H. Accordingly, in the first step, the thermal decomposition of the solidified film H is more reliably prevented.

The first temperature is equal to or higher than the boiling point of the dry assistant liquid F. Accordingly, in the first step, the dry assistant liquid F is more reliably removed.

The first temperature is equal to or higher than the boiling point of the ultraviolet curable material. Accordingly, in the first step, the dry assistant liquid F is more reliably removed.

The second temperature is higher than the first temperature. Thus, in the second step, the solidified film H is suitably thermally decomposed.

The second temperature is equal to or higher than the thermal decomposition temperature of the solidified film H. Accordingly, in the second step, the solidified film H is more suitably thermally decomposed.

(3) In the embodiment, the irradiation region of the irradiation unit 31 is larger than the upper surface WS1 of the substrate W. The irradiation unit 31 according to the embodiment does not move in the horizontal direction with respect to the substrate W held by the substrate holder 13. The irradiation unit 31 according to the embodiment does not move in the vertical direction Z with respect to the substrate W held by the substrate holder 13. However, the present invention is not limited thereto. For example, the irradiation region of the irradiation unit 31 may be smaller than the upper surface WS1 of the substrate W. For example, the irradiation unit 31 may move in the horizontal direction with respect to the substrate W held by the substrate holder 13. For example, the irradiation unit 31 may move in the vertical direction Z with respect to the substrate W held by the substrate holder 13.

FIG. 15 is a diagram illustrating a construction of a treating unit according to the modified embodiment. Like numerals are used to identify like components which are the same as those in the embodiment, and the components will not particularly be described. The irradiation unit 31 includes a light emitting unit 52. The light emitting unit 52 emits ultraviolet rays. The ultraviolet irradiation region by the light emitting unit 52 is smaller than the upper surface WS1 of the substrate W. The light emitting unit 52 is smaller than the light emitting unit 32 according to the embodiment. The light emitting unit 52 is electrically connected to the power source 36 (not illustrated).

The irradiation unit 31 includes a movement mechanism 53. The movement mechanism 53 moves the light emitting unit 52. The movement mechanism 53 moves the light emitting unit 52 to, for example, a first position Q1, a second position Q2, or a third position Q3. The first position Q1 is located above a first side of the substrate W held by the substrate holder 13 in side view. The second position Q2 is located above a second side of the substrate W held by the substrate holder 13 in side view. The second position Q2 has the same height as the first position Q1. The third position Q3 is higher than the first position Q1 and the second position Q2.

The movement mechanism 53 includes, for example, a horizontal movement mechanism 54 and a vertical movement mechanism 55. The horizontal movement mechanism 54 supports the light emitting unit 52. The horizontal movement mechanism 54 moves the light emitting unit 52 in the horizontal direction. The vertical movement mechanism 55 supports the horizontal movement mechanism 54. The vertical movement mechanism 55 moves the horizontal movement mechanism 54 in the vertical direction Z.

An example of movement of the light emitting unit 52 will be described. In the treatment liquid supply step and the application step, the light emitting unit 52 is located at the third position Q3. Accordingly, when the nozzles 22a and 22b move to the treatment position, the nozzles 22a and 22b do not interfere with the light emitting unit 52. In the curing step, the light emitting unit 52 moves from the third position Q3 to the first position Q1. While the light emitting unit 52 emits ultraviolet rays, the light emitting unit 52 moves from the first position Q1 to the second position Q2. The ultraviolet irradiation region moves on the substrate W. As a result, the upper surface WS1 of the substrate W is entirely irradiated with ultraviolet rays. The dry assistant liquid F on the substrate W is entirely irradiated with ultraviolet rays.

According to the modified embodiment, the light emitting unit 52 is relatively small. Thus, it is easy to downsize the treating unit 11.

(4) In the embodiment, the heating unit 41 heats the solidified film H through the substrate W. However, the present invention is not limited thereto. For example, the heating unit 41 may directly heat the solidified film H. For example, the heating unit 41 may transfer heat to the solidified film H without passing through the substrate W.

(5) In the embodiment, the heating unit 41 faces the lower surface WS2 of the substrate W. However, the present invention is not limited thereto. The heating unit 41 may face the upper surface WS1 of the substrate W. According to the modified embodiment, the heating unit 41 directly heats at least one of the dry assistant liquid F or the solidified film H. The heating unit 41 transfers heat to at least one of the dry assistant liquid F or the solidified film H without passing through the substrate W.

(6) In the embodiment, the application step, the curing step, and the thermal decomposition step were executed by the same treating unit 11. However, the present invention is not limited thereto. For example, the treating unit that executes the application step may be different from the treating unit that executes the curing step. For example, the treating unit that executes the application step may be different from the treating unit that executes the thermal decomposition step. For example, the treating unit that executes the curing step may be different from the treating unit that executes the thermal decomposition step. For example, one thermal decomposition step may be executed using two treating units.

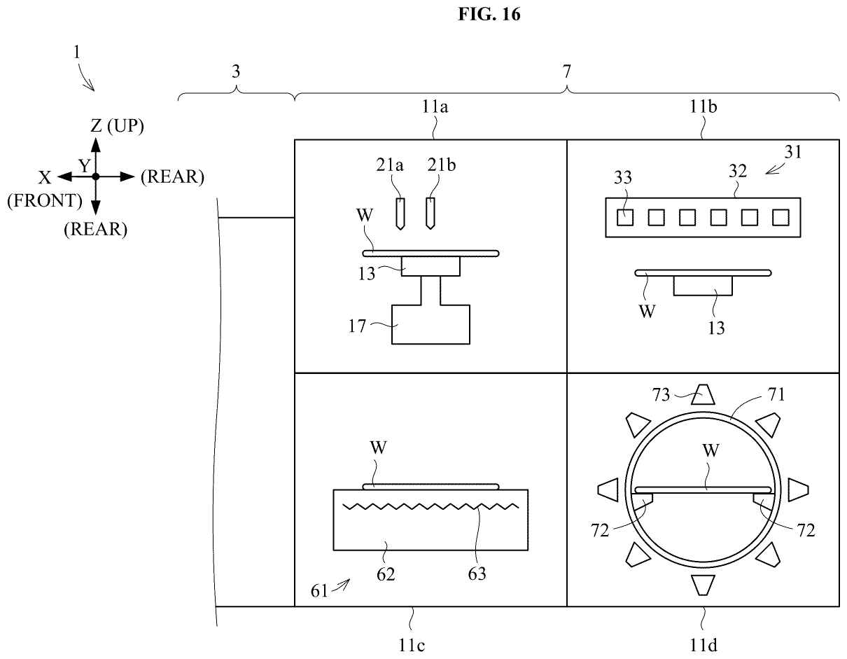

FIG. 16 is a left-side diagram illustrating a construction of a left portion of a substrate treating apparatus 1 according to the modified embodiment. Like numerals are used to identify like components which are the same as those in the embodiment, and the components will not particularly be described.

The treating block 7 includes treating units 11a. 11b, 11c, and 11d.

The treating unit 11a includes the substrate holder 13, the rotation driving unit 17, and the supply units 21a and 21b. In the treating unit 11a, the treatment liquid supply step and the application step are executed.

The treating unit 11b includes the substrate holder 13 and the irradiation unit 31. In the treating unit 11b, the curing step is executed.

The treating unit 11c includes a heating unit 61. The heating unit 61 heats the substrate W. The heating unit 61 includes a hot plate 62 and a heater 63. The hot plate 62 extends in the horizontal direction. The hot plate 62 has substantially the same size as the substrate W in plan view. The substrate W is placed on the hot plate 62. The hot plate 62 supports the substrate W in a horizontal posture. The heater 63 is attached to the hot plate 62. The heater 63 heats the substrate W on the hot plate 62. In the treating unit 11c, the thermal decomposition step is executed. More specifically, in the treating unit 11c, the first step is executed.

The treating unit 11d includes a substrate container 71, a substrate support unit 72, and a heating unit 73. The substrate W is accommodated in the interior of the substrate container 71. The substrate container 71 has, for example, a cylindrical shape. The substrate container 71 has, for example, a tube shape. The substrate container 71 allows transmission of infrared rays. The substrate container 71 is made of, for example, quartz glass. The substrate support unit 72 is installed in the interior of the substrate container 71. The substrate support unit 72 is supported by, for example, the substrate container 71. The substrate support unit 72 supports the substrate W in a horizontal posture. The heating unit 73 is installed externally of the substrate container 71. The heating unit 73 is arranged around the substrate container 71. The heating unit 73 emits, for example, infrared rays. The infrared rays are transmitted through the substrate container 71. The heating unit 73 irradiates the entire substrate W with infrared rays, for example. The heating unit 73 irradiates the dry assistant liquid F on the substrate W with infrared rays, for example. For example, the heating unit 73 irradiates the solidified film H on the substrate W with infrared rays. The heating unit 73 is, for example, a lamp heater. In the treating unit 11d, the thermal decomposition step is executed. More specifically, in the treating unit 11d, the second step is executed.

Although not illustrated, the transport mechanism 8 is configured to access each of the treating units 11a, 11b, 11c, and 11d.

An operation example of the substrate treating apparatus 1 will be described. First, the transport mechanism 8 transports the substrate W to the treating unit 11a. The transport mechanism 8 delivers the substrate W to the substrate holder 13 of the treating unit 11a. The treating unit 11a performs the treatment liquid supply step and the application step on the substrate W. The supply unit 21a supplies the treatment liquid L to the substrate W. Thereafter, the supply unit 21b applies the dry assistant liquid F to the substrate W.

Next, the transport mechanism 8 transports the substrate W from the treating unit 11a to the treating unit 11b. The transport mechanism 8 takes the substrate W from the substrate holder 13 of the treating unit 11a. The transport mechanism 8 delivers the substrate W to the substrate holder 13 of the treating unit 11b. The treating unit 11b performs the curing step on the substrate W. The irradiation unit 31 irradiates the dry assistant liquid F on the substrate W with ultraviolet rays. The solidified film H is formed on the substrate W.

Next, the transport mechanism 8 transports the substrate W from the treating unit 11b to the treating unit 11c. The transport mechanism 8 takes the substrate W from the substrate holder 13 of the treating unit 11b. The transport mechanism 8 places the substrate W on the hot plate 62 of the treating unit 11c. The treating unit 11c performs the thermal decomposition step on the substrate W. For example, the treating unit 11c performs the first step on the substrate W. The heating unit 61 (specifically, the heater 63) heats the substrate W at the first temperature. The dry assistant liquid F remaining on the substrate W is removed from the substrate W.

Next, the transport mechanism 8 transports the substrate W from the treating unit 11c to the treating unit 11d. The transport mechanism 8 takes the substrate W from the hot plate 62 of the treating unit 11c. The transport mechanism 8 delivers the substrate W to the substrate support unit 72 of the treating unit 11d. The treating unit 11d performs the thermal decomposition step on the substrate W. For example, the treating unit 11d performs the second step on the substrate W. The heating unit 73 heats the substrate W at the second temperature. The solidified film H on the substrate W is heated. The solidified film H on the substrate W is thermally decomposed. The substrate W is dried.

(7) In the curing step of the embodiment, the substrate W did not rotate. However, the present invention is not limited thereto. In the curing step, the substrate W may rotate. In the curing step, the dry assistant liquid F on the substrate W may be irradiated with ultraviolet rays while the substrate W is rotated.

(8) In the thermal decomposition step of the embodiment, the substrate W did not rotate. However, the present invention is not limited thereto. In the thermal decomposition step, the substrate W may rotate. In the thermal decomposition step, the solidified film H on the substrate W may be thermally decomposed while the substrate W is rotated.

(9) In the embodiment, an example of the treatment liquid L has been described. However, the present invention is not limited thereto. For example, the treatment liquid L may be a chemical liquid. For example, the treatment liquid L may be an etching liquid.

(10) In the treatment liquid supply step of the embodiment, one treatment liquid L was supplied to the substrate W. However, the present invention is not limited thereto. In the treatment liquid supply step, a plurality of treatment liquids may be supplied to the substrate W. For example, in the treatment liquid supply step, a first treatment liquid may be supplied to the substrate W, and then a second treatment liquid may be supplied to the substrate W. Here, the composition of the second treatment liquid is different from the composition of the first treatment liquid.

(11) In the embodiment, the treatment liquid supply step was executed before the drying step. However, the present invention is not limited thereto. For example, the treatment liquid supply step need not be executed before the drying step. For example, the treatment liquid supply step may be omitted.

(12) In the embodiment, when the drying step was executed, a liquid (e.g. the treatment liquid L) was present on the substrate W. That is, in the application step, the dry assistant liquid F was supplied to the substrate W in a wet state. However, the present invention is not limited thereto. For example, when the drying step is executed, the liquid (e.g. the treatment liquid L) need not be present on the substrate W. For example, in the application step, the dry assistant liquid F may be supplied to the substrate W in a dried state.

(13) In the embodiment, the pattern P on the substrate W may be formed on the substrate W, for example, before the substrate treating method is executed. Alternatively, the pattern P may be formed on the substrate W, for example, in the treatment liquid supply step.

(14) The embodiment and modified embodiments described in (1) to (13) above may be further varied as appropriate by replacing or combining their constructions with the constructions of the other modified embodiments.

### REFERENCE SIGNS LIST

1 substrate treating apparatus
10 controller
11, 11a, 11b, 11c, 11d treating unit
13 substrate holder
21a supply unit (treatment liquid supply unit)
21b supply unit (dry assistant liquid supply unit)
31 irradiation unit
41, 61, 73 heating unit
F dry assistant liquid
G liquid film
H solidified film
L treatment liquid
W substrate
WS surface of substrate
WS1 upper surface of substrate
P pattern
A projection

1. A substrate drying method for drying a substrate on which a pattern is formed,
the substrate drying method comprising:
an application step of applying a dry assistant liquid containing an ultraviolet curable material to the substrate;
a curing step of irradiating the dry assistant liquid on the substrate with ultraviolet rays to form a solidified film on the substrate; and
a thermal decomposition step of heating the solidified film to thermally decompose the solidified film and drying the substrate.

2. The substrate drying method according to claim 1, wherein
the solidified film has thermal decomposability.

3. The substrate drying method according to claim 1, wherein,
in the thermal decomposition step, the solidified film is heated at a temperature equal to or higher than a thermal decomposition temperature of the solidified film.

4. The substrate drying method according to claim 1, wherein
in the thermal decomposition step, the solidified film is removed from the substrate by thermal decomposition of the solidified film.

5. The substrate drying method according to claim 1, wherein,
in the thermal decomposition step, the solidified film is gasified.

6. The substrate drying method according to claim 1, wherein,
in the thermal decomposition step, the solidified film is decomposed into a plurality of particles, and the particles float from the substrate.

7. The substrate drying method according to claim 1, wherein,
in the thermal decomposition step, the solidified film is removed from the substrate without being melted.

8. The substrate drying method according to claim 1, wherein,
in the curing step, the ultraviolet curable material becomes a polymer,
the solidified film contains the polymer, and
in the thermal decomposition step, the polymer is thermally decomposed.

9. The substrate drying method according to claim 1, wherein the ultraviolet curable material is a liquid.

10. The substrate drying method according to claim 1, wherein
the ultraviolet curable material does not contain a polymer.

11. The substrate drying method according to claim 1, wherein
the ultraviolet curable material is isobornyl acrylate.

12. The substrate drying method according to claim 1, wherein
the ultraviolet curable material is an isobornyl acrylate monomer.

13. The substrate drying method according to claim 1, wherein
the dry assistant liquid does not contain a solvent.

14. The substrate drying method according to claim 1, wherein
the dry assistant liquid further contains a polymerization initiator.

15. A substrate treating method for treating a substrate on which a pattern is formed, the substrate treating method comprising:
a treatment liquid supply step of supplying a treatment liquid to the substrate; and
a drying step of executing the substrate drying method described in claim 1.
